(19) United States
(12) Patent Application Publication
(10) Pub. No.: US 2002/0034881 A1
(43) Pub. Date: Mar. 21, 2002

(54) Process for etching silicon wafers

(76) Inventors: Milind S. Kulkarni, St. Louis, MO (US); Henry F. Erk, St. Louis, MO (US); Judith Schmidt, St. John, MO (US)

Correspondence Address: SENNIGER POWERS LEAVITT AND ROEDEL, ONE METROPOLITAN SQUARE, 16TH FLOOR, ST LOUIS, MO, 63102, US

(21) Appl. No.: 09/896,945

(22) Filed: Jun. 29, 2001

Related U.S. Application Data
(60) Provisional application No. 60/215,612, filed on Jun. 30, 2000.

(51) Int. Cl. H01L 21/302

(52) U.S. Cl. 438/753

(57) ABSTRACT

The present invention relates to an aqueous etching solution, a method for tailoring the composition of the solution to provide a desired surface quality for a given quantity of stock to be removed, a process for etching a silicon wafer using said solution.

### REFERENCE TO RELATED APPLICATION

This application claims priority from U.S. provisional application, U.S. Serial No. 60/215,612, filed on Jun. 30, 2000.

### BACKGROUND OF THE INVENTION

The process of the present invention generally relates to the etching of semiconductor wafers. More particularly, the present invention relates to an aqueous etching solution, a method for tailoring the composition of the solution to provide a desired surface quality for a given quantity of stock to be removed, and a process for etching a silicon wafer using said solution.

Semiconductor wafers are typically obtained from single crystal silicon ingots using numerous process steps. The silicon wafers are sliced from single crystal silicon ingots and then subjected to various shaping and cleaning processes such as slicing, lapping, grinding, edge profiling, chemical etching and polishing to flatten and smooth the surface of the wafer and numerous cleaning steps throughout the process to eliminate contaminants to produce a wafer having a smooth, flat and clean surface. Typically, wafers are only polished on one side of the wafer referred to as the “polished side” or “front side” upon which integrated circuits may be produced by device manufacturers. After the wafer is sliced from the ingot and prior to the cleaning and shaping processes being performed, the wafers are frequently marked with bar codes to identify the wafer. The bar codes consist of series of dots marked on the surface of the wafer by a laser beam. These “hard laser marked” bar codes may then be read by a bar code reader to identify the wafer during or after the wafer manufacturing process. Device manufacturers often require the wafer to be hard laser marked with bar codes and often reject wafers having bar codes that are no longer readable. Generally, the bar codes are placed on the back side surface of the wafer, or on the surface opposite the surface upon which the integrated circuits may be produced. Accordingly, the backside of the wafer remains “as etched” and is typically not subjected to a final polishing process.

After the wafer is sliced and optionally hard laser marked with a bar code, the wafer is subjected to the various shaping and cleaning processes. Prior to chemical etching, silicon semiconductor wafers typically exhibit surface and/or subsurface damage such as embedded particles and physical damage such as micro-cracks, fractures or stress imparted to the wafer by upstream processes such as lapping, grinding and edge profiling. The damage generally occurs in the region extending from the surface of the wafer to at least 2.5 μm, and more typically at least 5 μm or greater below the surface of the wafer. Device manufacturers require a wafer that is substantially free of surface and subsurface damage. Thus, typical processes subject the wafer surface to a chemical etching step to remove a layer of stock having a thickness of at least about 5 μm or greater from the wafer surface, with the minimum removal quantity required to provide a substantially damage free surface being determined by the amount of damage caused by the previous process steps.

In addition to the surface and subsurface damage discussed above, wafers typically exhibit a characteristic surface roughness, which appears as jagged surface undulations characterized by a peak to peak distance of less than about 1 mm and typically less than about 100 μm and even more typically less than 1 μm and an amplitude or vertical distance from peak to valley of at least about 0.05 μm, and typically at least about 0.1 μm and even more typically at least about 0.2 μm. The roughness of a wafer surface is often measured directly using surface topology measuring instruments, or alternatively, is determined indirectly by measuring the gloss or reflectance of the surface of the wafer. A rough wafer surface tends to scatter light incident on the surface. Thus, wafers having increased roughness on the surface tend to have low gloss values, while wafers having decreased roughness tend to have high gloss values. Device manufacturers generally require that wafers meet particular roughness and/or gloss specifications after etching since the backside surface of the wafer is typically not polished. More stringent requirements are generally required for the front surface where the integrated circuit is to be formed. Thus, wafer manufacturers typically subject the surface of the wafer to a final polishing step to reduce the roughness and increase the gloss to meet the specifications set by the device manufacturers. Although the final roughness or gloss of a wafer is generally determined in the final polishing step for the front surface, the roughness or gloss of the surface prior to polishing directly affects the throughput of the polishing process and therefore affects the overall cost of the wafer manufacturing process. Furthermore, since the back surface is typically not polished, wafer manufacturers prefer using an etching process that improves the gloss of the wafer surface in addition to removing a layer of stock from the surface of the wafer to eliminate surface and subsurface damage, such that the gloss is improved on both surfaces prior to the final polishing step.

Etchants or etching solutions in routine use typically contain at least three components, a strong oxidizing agent, such as nitric acid, potassium dichromate, or permanganate to oxidize the surface of the wafer, a dissolving agent, such as hydrofluoric acid, which chemically dissolves the oxidation product, and a diluent such as acetic acid or phosphoric acid. The relative proportion of these acids is typically selected somewhat arbitrarily and the removal quantity required to produce a wafer having a desired gloss is determined by trial and error. While it is desirable to remove as little material as necessary to improve the yield of the wafer manufacturing process, enough material must be removed to remove the surface and subsurface damage and achieve the desired gloss characteristics. However, the removal quantity required to yield a desired gloss value using given aqueous etching solution composition may greatly exceed the minimum required removal quantity needed to eliminate the surface and subsurface damage, resulting in an inefficient etching process that removes excessive quantities of silicon from the surface of the wafer. Moreover, even if a particular composition of an aqueous etching solution happens to provide the desired gloss without removing excessive quantities of silicon, changes in the upstream processes can increase or decrease the depth at which the subsurface damage occurs, altering the minimum required removal quantity such that the aqueous etching solution no longer provides an efficient etching process. Finally, the aqueous etching solutions described above frequently distort the laser dots placed on the surface of the wafer prior to etching to identify the wafer. The laser dots can swell in diameter such that they are no longer readable by the bar code reader, resulting in the wafers being no longer suitable for the device manufacturer.

In view of the forgoing, a need continues to exist for an aqueous etching solution, a method for determining the composition of the aqueous etching solution and method for etching the surface of a wafer using the aqueous etching solution such that a desired surface quality may be achieved after a predetermined quantity of silicon has been removed, preferably without destroying the readability of the hard laser marked bar codes.

### SUMMARY OF THE INVENTION

Among the objects of the invention, therefore, may be noted the provision of an aqueous etching solution; a method for determining the composition of the solution; a process for using said solution for producing uniformly etched wafers; the provisions of an aqueous etching solution and process for etching wherein the composition of the aqueous etching solution is selected to minimize the excess stock removal while producing etched wafers having a desired surface quality; the provision of an acid etching process and a method for determining the composition of the solution used therein to reduce the surface irregularities caused by bubbles of reaction byproducts and extrinsic gases used in etching adhering to the surface or the bubble masking effect; the provision of an acid etching process using a two component aqueous etching solution; the provision of an aqueous etching solution and process for etching hard laser marked wafers such that the etched wafers exhibit enhanced bar coded readability; the provision of an aqueous etching solution which improves the throughput of the etching step; the provision of an aqueous etching solution and process for etching which improves the throughput of subsequent polishing steps; and the provision of an aqueous etching solution and process for etching which reduces operating cost of the etching process.

Briefly, therefore, the present invention is directed to a process for etching silicon semiconductor wafers wherein at least one surface of the silicon wafer is contacted with an aqueous etching solution comprising hydrofluoric acid, an oxidizing agent and optionally a diluent, wherein the concentration of hydrofluoric acid and optionally the diluent and/or the oxidizing agent in the aqueous etching solution is selected to manipulate the effective liquid phase diffusion time scale or effective mass transfer time scale quantified in terms of an effective mass transfer resistance, R_{m,eff,i}, and the time scale of chemical kinetics quantified in terms of a kinetic resistance, R_{r,i}, of the etching environment to provide a desired ratio between the surface quality of the etched wafer and the quantity of silicon removed during the etching process, such that upon removing a desired quantity of silicon from the surface of the wafer, the resulting etched surface has a desired surface quality.

The present invention is further directed to a process for etching silicon semiconductor wafers wherein the concentration of the oxidizing agent is in excess of the amount required to oxidize the silicon to be removed, and the concentration of the hydrofluoric acid and diluent in the aqueous etching solution are selected by first determining a relationship between a surface quality and a removal quantity over a range of hydrofluoric acid concentrations and a range of diluent concentrations in the aqueous etching solution according to the following method (a) etching a silicon sample in the etching environment by contacting the sample with a calibrated aqueous etching solution comprising a known concentration of hydrofluoric acid, oxidizing agent, and diluent for a period of time to remove a quantity of silicon from the surface of the sample;

(b) determining the quantity of silicon removed from the surface of the sample in step (a) and the surface quality of the etched sample;

(c) repeating steps (a) and (b) for different contact times to determine the relationship between the surface quality and the quantity of silicon removed from the surface of the sample in the etching environment for the composition of the calibrated aqueous etching solution of step (a);

(d) repeating steps (a) through (c) using calibrated aqueous etching solutions having various known concentrations of hydrofluoric acid and optionally various known quantities of diluent; and

(e) determining the concentration of hydrofluoric acid and optional diluent in the aqueous etching solution that will produce an etched wafer such that the surface of the etched wafer has the desired surface quality once the desired quantity of silicon has been removed from the surface of the etched wafer in the etching environment based on the relationships between the surface quality and the quantity of silicon removed from the surface of the sample in the etching environment for the calibrated aqueous etching solutions of steps (a) through (d).

The present invention is directed to a process for etching a silicon semiconductor wafer having a hard laser marked bar code, wherein at least one surface of the silicon wafer is contacted with an aqueous etching solution comprising hydrofluoric acid, an oxidizing agent and a diluent, wherein the concentration of hydrofluoric acid and the diluent in the aqueous etching solution is selected to manipulate an effective mass transfer resistance, R_{m,eff,i}, and a kinetic resistance, R_{r,i}, of the etching environment to manipulate the ratio between the effective mass transfer resistance, R_{m,eff,i}, and the kinetic resistance, K_{r,i}, of the etching environment such that the readability of the hard laser marked bar code on the etched surface is not destroyed by the etching process.

Finally, the present invention is directed to maintaining the etching solution composition in the immersion-type etching environment during the etching cycle by the addition of hydrofluoric acid, the required oxidant and optional diluent at a rate required by species balance to maintain the constant composition of the etching solution.

### BRIEF DESCRIPTION OF THE DRAWINGS

FIGS. 1a and 1b are graphs which show examples of how the polishing efficiency of the etching process changes with increases in the ratio of the effective mass transfer resistance, R_{m,eff,i}, to the kinetic resistance, R_{r,i}, wherein the ratio is varied by increasing the film thickness while maintaining a constant effective diffusivity (1a) and wherein the ratio is varied by decreasing the effective diffusivity while maintaining a constant film thickness (1b).

FIG. 2 is a schematic diagram showing the bubble masking effect on a laser dot.

FIGS. 3a, 3b, 3c and 3d show the relationship between the normalized surface roughness, Φ, and the removal quantity, Y, for etching solutions having varying hydrofluoric acid, HF, and thickener (i.e., phosphoric acid), THK, concentrations.

FIGS. 4a and 4b are histograms showing the variation in gloss values for the fast etch process (4a) and the conventional etch process (4b).

FIGS. 5a and 5b show the flatness at various locations across the surface of a wafer etched by conventional methods (5a) and by the method of the present invention (5b).

FIGS. 6a and 6b are schematic drawings showing the etching configuration and modified etching configuration used in the etching experiments.

FIG. 7 shows the flatness at various locations across the surface of a wafer etched using the modified etching configuration.

FIGS. 8a and 8b are images showing bar codes on the surface of a wafer after etching the wafer by a conventional process (8a) and after etching the wafer by the process of the present invention (8b).

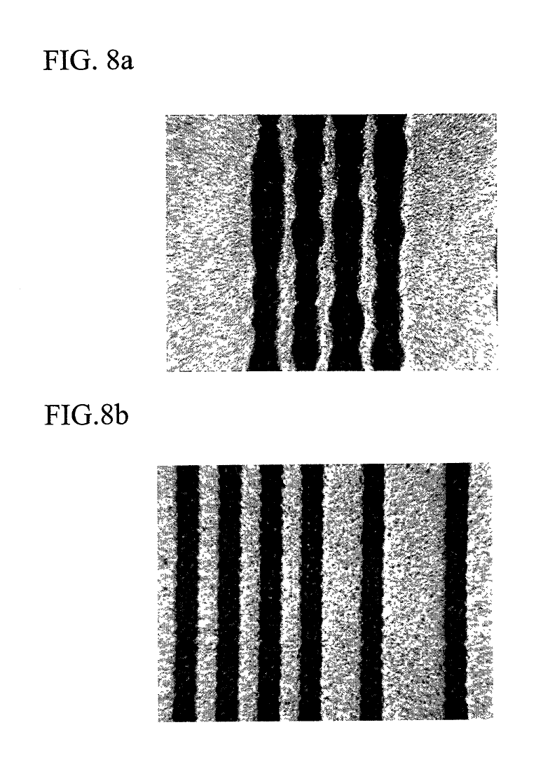

FIGS. 9a and 9b are graphs showing the effect of extrinsic bubbling on gloss (9a) and roughness (9b).

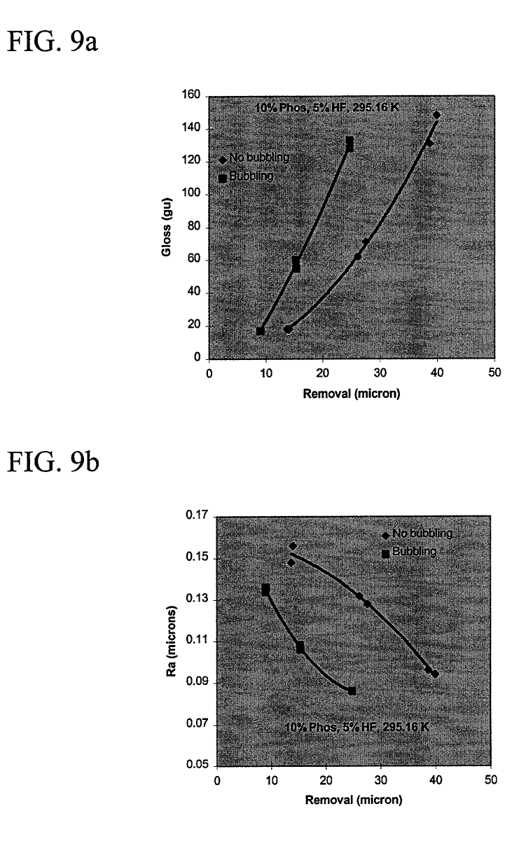

### DETAILED DESCRIPTION OF THE INVENTION

In accordance with the present invention, a method has been discovered for determining the relationship between the composition of an aqueous etching solution, the surface quality of an etched wafer and the amount of silicon removed from the surface of the wafer after etching the wafer in an etching environment. Upon determining the quantity of silicon to be removed from the wafer and the desired quality of the surface of the etched wafer, an aqueous etching solution can be selected based on the determined relationship such that upon etching the wafer using the selected solution to remove the determined quantity of silicon, the etched surface will exhibit the desired surface quality. Furthermore, by appropriately selecting the aqueous etching solution according to the method of the present invention, a semiconductor wafer having been previously subjected to a hard laser marked bar coding process may be etched to improve the surface quality without destroying the readability of the hard laser marked bar code.

The present invention allows the concentration of the aqueous etching solution to be selected to affect both the effective mass transfer resistance, R_{m,eff,i}, that inhibits the reactants from coming in contact with the surface of the wafer, and the kinetic resistance, R_{r,i}, that controls the rate at which the reactants oxidize and remove silicon from the surface of the wafer. By affecting the ratio of effective mass transfer resistance, R_{m,eff,i}, to kinetic resistance, R_{r,i}, the quality of the etched surface may be increased or decreased for a given amount of silicon removed in the etching process. Furthermore, the ratio of effective mass transfer resistance, R_{m,eff,i}, to kinetic resistance, R_{r,i}, may be manipulated in such a manner that the occurrence of bubble masking may be reduced to allow etching the wafer surface without substantially deteriorating hard laser marked bar codes. Because the precise effective mass transfer and kinetic resistances are difficult to measure, the present invention utilizes a method wherein the concentration effects are empirically determined as a function of surface quality and removal quantity.

Typical etching processes involve exposing the surface of a silicon wafer to an aqueous etching solution comprising an oxidizing agent to oxidize the silicon at the surface and a dissolving agent, such as hydrofluoric acid, to remove the oxidized silicon from the surface. Some of the byproducts of the etching reactions typically occur in gaseous form. For example, aqueous etching solutions comprising nitric acid and hydrofluoric acid may produce oxides of nitrogen and/or hydrogen gases. The etching mechanism includes the following steps: (1) transport of the reactants in liquid phase from the bulk aqueous etching solution to the wafer surface; (2) reaction(s) on the wafer surface, producing products in both liquid and gas phase; (3) detachment of gaseous products from the silicon surface; and, (4) transport of liquid and gaseous products to the bulk aqueous etching solution.

The overall etching rate is affected by both the effective mass transfer resistance, R_{m,eff,i}, and the kinetic resistance, P_{r,i}, of a particular etching process. Both the reactants and products of the reaction must pass through a stagnant liquid film or effective mass transfer film which provides a finite effective mass transfer resistance, R_{m,eff,i}, before the reactants can react with the silicon on the surface of the wafer and before the products of those reactions may successfully leave the surface. The effective mass transfer resistance, R_{m,eff,i}, represents resistances for liquid phase transport of reagents and bubbles as well as the resistance for the bubble detachment from the surface. The effective mass transfer film thickness and accordingly the effective mass transfer resistance, R_{m,eff,i}, depends on the hydrodynamics of the etching environment, the viscosity of the aqueous etching solution and a bubble masking effect discussed in more detail below. Accordingly, the effective mass transfer resistance, R_{m,eff,i}, directly affects the rate of steps (1), (3) and (4) of the etching process. The kinetic resistance, R_{r,i}, of an etching process directly affects the rate of step (2) of the etching process. The kinetic resistance, R_{r,i}, is a function of the chemical reaction kinetics and, therefore, depends on the temperature of the etching environment and the concentrations of the reactants on the wafer surface which are influenced by the concentrations of reactants in the aqueous etching solution. When the effective mass transfer and kinetic resistances are comparable in magnitude, both kinetic and effective mass transfer resistances affect the rate of etching. However, when the difference in the kinetic and effective mass transfer resistances is significant, the higher resistance controls the overall etch rate. Since effective mass transfer resistance, R_{m,eff,i}, and kinetic resistance, R_{r,i}, influence each other, steps (1) through (4) are effectively influenced by both resistances. In typical etching environments, etch rates are generally controlled by the effective mass transfer resistance, R_{m,eff,i}.

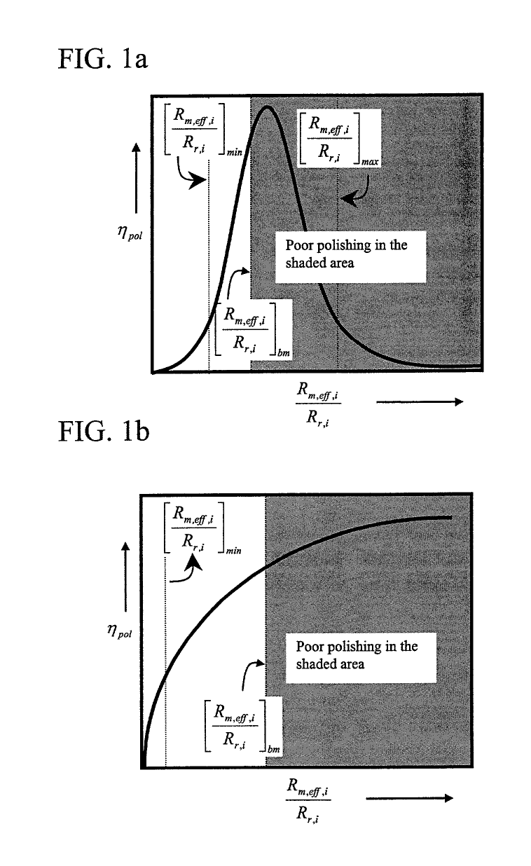

The quality of the surface of a silicon wafer is typically measured as surface roughness or gloss, wherein the roughness of a wafer is a measure of surface topology, and gloss is a measure of light reflected off of the surface of the wafer. As stated earlier, a rough wafer surface tends to scatter light reflected off of the surface. Thus, wafers having increased roughness on the surface tend to have low gloss values, while wafers having decreased roughness tend to have high gloss values. Without being held to a particular theory, it is believed that the surface quality, such as gloss or roughness, of an etched surface produced by etching a specified quantity of silicon from the surface of a wafer using an acidic aqueous etching solution can be affected by manipulating the effective mass transfer resistance, R_{m,eff,i}, and kinetic resistance, R_{r,i}, of the etching environment. More precisely, the ratio between the gloss of the etched wafer and the amount of silicon removed in the etching process, hereinafter referred to as the gloss to removal ratio which is often used as a measure of the polishing efficiency, ηₚₒₗ, of an etching solution, increases with increases in the ratio of effective mass transfer resistance, R_{m,eff,i}, to kinetic resistance, R_{r,i}, for a particular etching environment, reaches a maximum and then asymptotically decreases as shown in FIG. 1a. Preferably, the etching is performed at an effective mass transfer resistance, R_{m,eff,i}, to kinetic resistance, R_{r,i}, ratio such that increases in the ratio result in increases in the polishing efficience (i.e., at a ratio less than the ratio corresponding to the maximum polishing efficiency). Correspondingly, the ratio of surface roughness of the surface of the etched wafer to the amount of silicon removed in the etching process, hereinafter referred to as the roughness to removal ratio, decreases with increases in the ratio of effective mass transfer resistance, R_{m,eff,i}, to kinetic resistance, R_{r,i}, in an etching environment, reaches a minimum and then asymptotically increases. In some cases, depending on the etching solution, the gloss to removal ratio increases with increases in the ratio of the effective mass transfer resistance, R_{m, eff,i}, to the kinetic resistance, R_{r,i}, and asymptotically approaches a maximum as shown in FIG. 1b. Correspondingly, the roughness to removal ratio decreases with increases in the ratio of effective mass transfer resistance, R_{m,eff,i}, to kinetic resistance, R_{r,i}, in an etching environment, and asymptotically approaches a minimum value. It should be noted that the polishing efficiency for the etching process referred to herein, describes the decrease in surface roughness caused by the etching process and not by subsequent mechanical or chemo-mechanical surface smoothing processes (i.e., conventional “polishing” processes.) Increases in the effective mass transfer resistance, R_{m,eff,i}, are generally the result of increases in the thickness of the mass transfer film located directly on the surface of the wafer as a result of changes in the hyrodynamic conditions of the etching environment. The presence of the film and corresponding effective mass transfer resistance, R_{m,eff,i}, reduces the surface roughness during etching by affecting the relative etch rates at peaks and valleys on the surface of the wafer. More specifically, since the effective mass transfer film is thinner at peaks on the surface of the wafer than at valleys on the surface of the wafer, reactants can more readily attack the peaks than valleys due to the lower local effective mass transfer resistence. Stated differently, the reactants and products of the etching process can more rapidly contact and dislodge from the surface of the peaks than at the valleys due to the lower effective mass transfer resistance, R_{m,eff,i} near the peak that at the valleys. For a given effective mass-transport film thickness, the difference in the etching rate between peaks and valleys further increases with a decreasing effective diffusivity of the reactants. The effective mass transfer resistance, R_{m,eff,i}, can be increased by adding a diluent such as phosphoric acid, acetic acid, sulfuric acid or mixtures thereof. The addition of a diluent can affect both the effective mass-transport film thickness and the diffusivity of the reactants, and therefore change the effective mass-transport resistance. Accordingly, such diluents may be added at high concentrations to the aqueous etching solutions such that etched wafers with higher gloss and lower roughness can be produced with lower removal quantities.

The gaseous by-products of acid etching processes form bubbles which are herein referred to as “intrinsic bubbles”; whereas non-reactive gas bubbles which are conventionally injected into etching solutions to enhance mixing are herein referred to as “extrinsic bubbles”. Intrinsic bubbles adhere to the silicon surface for a period of time before they are dislodged. The presence of intrinsic bubbles on the surface of the wafer as well as intrinsic bubbles that have dislodged but not yet left the effective mass transfer film also affect the effective mass transfer resistance, R_{m,eff,i}, of the etching process, creating a so called “bubble masking effect.” Moreover, the etching reaction does not take place where intrinsic or extrinsic bubbles are attached to the surface of the wafer, thus affecting the surface morphology. That is, sites on the wafer surface masked by bubbles form peaks during the etching process since no etching takes place on sites covered by bubbles. Thus, while the bubble masking effect tends to increase the effective mass transfer resistance, R_{m,eff,i}, it also deteriorates the quality of the surface of the wafer.

The intensity of the bubble masking effect on the surface is related to the ratio between the bubble transport resistance from the surface of the wafer to the bulk of the solution and the bubble formation resistance. Bubble formation resistance is related to the kinetic resistance, R_{r,i}, of the etching process. That is, as the kinetic resistance, R_{r,i}, decreases, the bubble formation resistance decreases resulting in an increase in the formation of intrinsic bubbles, i.e., the bubble formation time scale decreases. The bubble transport resistance increases with increases in the effective mass transfer resistance, R_{m,eff,i}, surface tension and silicon surface morphology. Therefore, since the viscosity of the aqueous etching solution and the hydrodynamics of the etching environment affect the effective mass transfer resistance, R_{m,eff,i}, they correspondingly affect the bubble transport resistance. If the ratio of the bubble transport resistance to the bubble formation resistance is greater than a critical bubble masking resistance ratio, specific to each etching environment, the etching process produces an uneven surface with peaks caused by the bubble masking effect. Under such conditions, intrinsic bubbles formed on the surface stay on the surface long enough to cause appreciable difference in the removal between masked and unmasked sites. Conversely, when the ratio of bubble transport resistance to the bubble formation resistance is smaller than this critical ratio, intrinsic bubbles show negligible masking effect, i.e., intrinsic bubbles are dislodged from the surface before appreciable difference in removal between masked and unmasked sites develops.

Since the bubble transport resistance increases with increases in the effective mass transfer resistance, R_{m,eff,i}, and the bubble formation resistance increases with increases in the kinetic resistance, R_{r,i}, there exists a critical ratio of effective mass transfer resistance, R_{m,eff,i}, to the kinetic resistance, R_{r,i}, above which bubble masking deteriorates the surface of the wafer at such a rate that the polishing efficiency of the etching process is decreased. This critical ratio for bubble masking can occur before or after the critical ratio of the effective mass transfer resistance, R_{m,eff,i}, to kinetic resistance, R_{r,i}, for which the theoretical polishing efficiency reaches a maximum under no bubble masking conditions. Thus, as shown in FIG. 1a, for increasing effective mass transport film thicknesses, the gloss to removal ratio, i.e., the polishing efficiency, ηₚₒₗ, initially increases with increases in the ratio between the effective mass transfer resistance, R_{m,eff,i}, and the kinetic resistance, R_{r,i} (referred to hereinafter as the effective mass transfer resistance, R_{m,eff,i}, to kinetic resistance, R_{r,i}, ratio); however, as the bubble masking effect increases due to increases in the effective mass transfer resistance, R_{m,eff,i}, the increasing deterioration in the surface quality due to the bubble masking effect eventually causes the gloss to removal ratio i.e., the polishing efficiency, _{ηpol}, to decrease, wherein the peak represents the maximum theoretical polishing efficiency under no bubble masking. Similar surface deterioration by bubble masking occurs if the effective mass-transport resistance increases because of decreasing effective diffusivity. Furthermore, although the optimum gloss to removal ratio for changing mass-transport film thicknesses occurs at quite high effective mass transfer resistances, surface irregularities frequently referred to by persons skilled in the art as “brain pattern” or “orange peal,” may be caused by bubble masking even prior to the maximum such that it is preferred to etch wafers at some level less than the optimum gloss to removal ratio, or polishing efficiency.

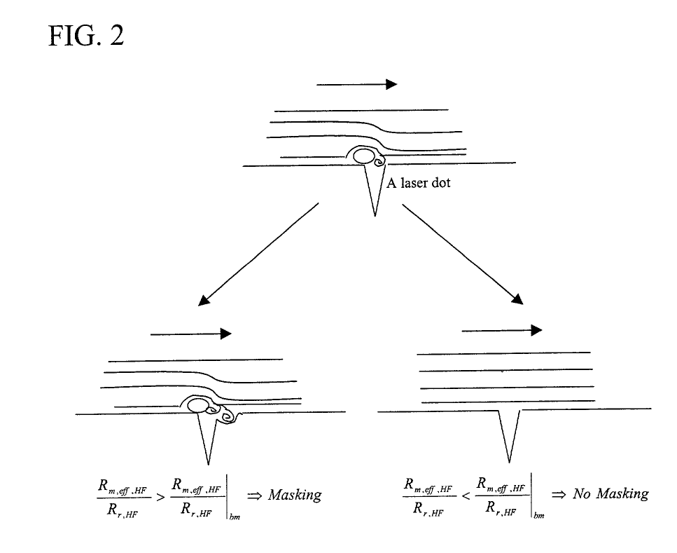

In addition to affecting the polishing efficiency of the etching process, the masking bubbles adhere to the damaged areas inside or around laser dots more strongly than on the rest of the wafer. Thus, the intrinsic bubbles typically do not disengage from surfaces inside or around laser dots, or at least the average residence time for intrinsic bubbles in the vicinity of the laser dots is higher than that on the rest of the wafer surface. Accordingly, damaged sites around and inside laser dots caused by the hard laser marking process exhibit a higher bubble masking effect resulting in surface irregularities in the vicinity of the laser dots. Additionally, because intrinsic bubbles adhere to the sites in and around the laser dots, the hydrodynamics of the aqueous etching solution is affected near the laser dots, causing variations in mixing intensity near the laser dot, creating pockets of local flow regimes having different mixing intensities. Since etching is a highly mass-transfer influenced process, mixing intensity greatly influences etch rates. The difference in local mixing intensities results in a difference in local etch rates that causes distortions in the laser dot geometry referred to as “laser dot blowout” as shown in FIG. 2.

Thus increasing the efficiency of the etching process by adding high concentrations of viscous diluent, increases the bubble masking effect near the laser dots, which results in the laser dot blowout. An acid mixture with a lower diluent concentration provides lower effective mass transfer resistance, R_{m,eff,i}, and, hence, minimizes the laser dot blowout. However, at lower diluent concentrations, polishing efficiency is also lower as a result of lower effective mass transfer resistance, R_{m.effi}. Thus, more silicon must be removed from the wafer surface to achieve a specified gloss or roughness on the etched surface.

Preferably, therefore, the ratio of effective mass transfer resistance, R_{m,eff,i}, to kinetic resistance, R_{r,i}, is increased by decreasing the kinetic resistance, R_{r,i}, and viscosity of the etching solution. The kinetic resistance, R_{r,i}, varies inversely with the concentration of the etching component in the aqueous etching solution. That is, by increasing the concentration of hydrofluoric acid in the aqueous etching solution, the kinetic resistance, R_{r,i}, decreases thereby increasing the reaction rate. Thus, according to the present invention, the concentration of hydrofluoric acid may be increased to increase the ratio of effective mass transfer resistance, R_{m,eff,i}, to kinetic resistance, R_{r,i}. Conversely, the concentration of hydrofluoric acid may be decreased to decrease the ratio of effective mass transfer resistance, R_{m,effi}, to kinetic resistance, R_{r,i}. Because the kinetic resistance, R_{r,i}, is primarily a function of the concentration of the dissolving agent (e.g., hydrofluoric acid), the oxidizing agent is preferably maintained at a concentration in excess of the stoichiometric quantity required to oxidize the amount of silicon to be removed.

Typical diluents, such as phosphoric acid, generally have a viscosity greater than hydrofluoric acid. The viscosity of the etching solution may be reduced by decreasing the concentration of diluent, which causes a corresponding reduction in the effective mass transfer resistance, R_{m,eff,i}. This reduction in the effective mass transfer resistance, R_{m,eff,i}, may be compensated for by reducing kinetic resistance, R_{r,i}, (i.e., by increasing the concentration of hydrofluoric acid) such that the ratio of effective mass transfer resistance, R_{m,eff,i}, to kinetic resistance, R_{r,i}, remains high. Increasing the hydrofluoric acid concentration and decreasing the concentration of viscous diluent not only increases the ratio of effective mass transfer resistance, R_{m,eff,i}, to the kinetic resistance, R_{r,i}, but also increases the critical bubble masking limit in the sense that the bubble masking effects remain negligible for higher effective mass transfer resistance, R_{m,eff,i}, to kinetic resistance, R_{r,i}, ratios. This allows a wider operating window in which a higher polishing efficiency can be achieved in the absence of significant bubble masking effects, which is not otherwise possible for high viscosity etching solutions. Thus, by increasing the hydrofluoric acid concentration and decreasing the viscous diluent concentration, a high gloss to removal ratio may be maintained and the bubble masking effect may be substantially reduced. Furthermore, for a given etching environment, there exists a relationship between the concentrations of hydrofluoric acid, diluent and oxidizing agent in the aqueous etching solution and the ratio of effective mass transfer resistance, R_{m,eff,i}, to kinetic resistance, R_{r,i}, such that the concentrations in the aqueous etching solution may be selected to affect the effective mass transfer resistance, R_{m,eff,i}, to kinetic resistance, R_{r,i}, ratio in the etching environment such that a desired ratio between the quality of the etched surface of a wafer and the amount of silicon removed from the surface by the etching process is achieved.

The etching process of the present invention employs as a starting material from a single crystal silicon semiconductor wafer sliced from a single crystal silicon ingot and further processed using conventional grinding apparatus to profile the peripheral edge of the wafer and to roughly improve the general flatness and parallelism of the front and back surfaces. Accordingly, the silicon wafer may be sliced from the ingot using any means known to persons skilled in the art, such as, for example, an internal diameter slicing apparatus or a wiresaw slicing apparatus. Additionally, once the wafer is sliced from the ingot, the peripheral edge of the wafer is preferably rounded to reduce the risk of wafer damage during further processing. The wafer is then subjected to a conventional grinding process to reduce the non-uniform damage caused by the slicing process and to improve the parallelism and flatness of the wafer. Such grinding processes are well known to persons skilled in the art. Typical grinding processes generally remove about 20 μm to about 30 μm of stock from each surface to roughly improve flatness using, for example, a resin bond, 1200 to 6000 mesh wheel operating at about 2000 RPM to about 4000 RPM. Frequently, wafers are subjected to multiple lapping processes wherein abrasive slurries containing abrasive particles ranging in size from about 3 μm to about 20 μm are used to remove about 5 μm to about 100 μm of stock from each surface to improve the flatness of the wafer.

The silicon semiconductor wafer may have any conductivity type and resistivity which is appropriate for a particular semiconductor application. Additionally, the wafer may have any diameter and target thickness which is appropriate for a particular semiconductor application. For example, the diameter is generally at least about 100 μm and typically is 150 mm, 200 mm, 300 mm or greater, and the thickness may be from about 475 μm to about 900 μm or greater, with the thickness typically increasing with increasing diameter. The wafer may also have any crystal orientation. In general, however, the wafers have a <100>or <111> crystal orientation.

Having been sliced from the ingot and subjected to the mechanical shaping processes described above, the wafer typically exhibits surface and/or subsurface defects such as embedded particles and physical damage such as micro-cracks, fractures or stress imparted into the wafer by upstream processes such as lapping, grinding and edge profiling. This damage generally occurs in the region extending from the surface of the wafer to at least about 2.5 μm or greater below the surface of the wafer. In addition, the surface of the wafer generally has a surface roughness of at least about 0.05 μm, and typically at least about 0.1 μm and even more typically at least about 0.2 μm. The surface roughness may be measured using any metrology device capable of measuring the surface roughness. Such devices are well known in the art. For example, the surface roughness may be measured using an MP 300 surface measurement device which is commercially available from Chapman Instruments (Rochester, N.Y. or other metrology devices such as an AFM microscope, a Nomarski microscope at 5×magnification, a Wyko-2D microscope equipped with a 10×magnification, or an optical interferometer. Alternatively, the surface quality may be determined indirectly by measuring the gloss of the surface of the wafer. The gloss may be measured using any metrology device capable of measuring the reflected light off the surface of the wafer. Such devices are well known in the art. For example, the gloss may be measured using a mirror-Tri-gloss metrology device which is commercially available from BYK-Gardner (Silver Springs, Md.).

The present invention uses an acidic aqueous etching solution to remove a desired quantity of silicon from the surface of the wafer to remove surface damage and improve the surface quality of the wafer. The amount of silicon removed from the surface of the wafer is preferably at least about 2.5 μm, more preferably at least about 5 μm and may be as much as 10 μm, 30 μm, or greater than 30 μm such that the region containing the damage described above is removed. Additionally, the present invention may be used to eliminate any other surface or subsurface damage which can be eliminated by removing silicon from the surface of the wafer, or simply to remove a desired amount of silicon from the surface of the wafer. The desired quality of the surface of the wafer is selected based on the desired quality of the finished wafer as determined by the device manufacturer, and by the efficiency of the polishing and etching processes.

Typically, the desired gloss or roughness values are selected based on customer specifications. However, in this regard it should be noted that as the desired surface quality is increased (i.e., the gloss increases and/or the desired roughness decreases), for a particular stock removal quantity, the ratio of effective mass transfer resistance, R_{m,eff,i}, to kinetic resistance, R_{r,i}, must be increased to provide the surface quality to removal quantity resulting in an increased degree of bubble masking. Furthermore, although the effective mass transfer resistance, R_{m,eff,i}, may be increased by adding a viscous diluent, increases in the viscous diluent concentration tends to increase the viscosity of the aqueous etching solution and, therefore, the bubble masking effect, and reduces the overall etching rate. Preferably therefore, the concentration of diluent is decreased to decrease the bubble masking effect while the hydrofluoric acid concentration is increased to decrease the kinetic resistance, Rᵣᵢ, and, thus, increase the effective mass transfer resistance, R_{m,eff,i}, to kinetic resistance, R_{r,i}, ratio.

However, increased concentrations of hydrofluoric acid may cause an increased degree of staining on the surface of the wafer. Without being held to a particular theory, it is believed that some of the stains produced by etching are sub-oxides of silicon that are not removed by the hydrofluoric acid. Sub-oxides of silicon are formed when the oxidizing capacity of the acid mixture becomes weaker. Therefore, an excess amount of nitric acid or other oxidizing agent in the aqueous etching solution is preferred.

In vertical etching environments, such as the vertical etching apparatus conventionally used to etch wafers, wafers are transferred from a mixed acid etch tank to a quick dump rinse tank. Typically there is a thin layer of aqueous etching solution attached to silicon wafers while being transferred from the mixed acid etch tank to the quick dump rinse tank. If the time period over which the wafer is transferred from the mixed acid etch tank to the quick dump rinse tank relative to the etching time scale is short, little etching occurs during the transfer. It should be noted that the time scale of a process varies inversely with the rate of the process. However, if the time period is high, or if the etch rate is sufficiently high, a significant amount of etching can take place while transferring wafers from mixed acid etch tank to quick dump rinse tank.

In addition, it is believed that if the etch rate is sufficiently high, efficient removal of oxides from the wafer surface does not take place during the transfer of the wafer from the mixed acid etch tank to the quick dump rinse tank, and the concentration of the products of the etching process on the wafer surface increases causing staining on the wafer surface. Thus, stain loss at very high etch rates increases as a result of mechanical limitations imposed by the minimum transfer time required to transfer the wafer from the mixed acid etch tank to the quick dump rinse tank. Accordingly, the desired quality of the etched surface is preferably selected to balance throughput of the final polishing process with the throughput of the etching process in addition to reducing bubble masking and stain effects. It is to be noted, however, that the desired quality of the etched surface may be selected without regard to the efficiency of the polishing process or the etching process without departing from the scope of the present invention.

In accordance with the present invention, therefore, the surface of the wafer is brought into contact with an aqueous etching solution. The aqueous etching solution comprises a concentration of oxidizing agent which is at least the stoichiometric concentration required to oxidize the silicon to be removed from the surface of the wafer, wherein the oxidizing agent is selected from a group consisting of potassium permanganate, potassium dichromate, ozone, hydrogen peroxide, nitric acid and mixtures thereof. Additionally, the aqueous etching solution comprises a concentration of hydrofluoric acid and optionally a diluent selected from a group consisting of acetic acid, phosphoric acid, sulfuric acid and mixtures thereof. The concentration of hydrofluoric acid and diluent in the aqueous etching solution are determined based on the empirically determined relationship between the surface quality of the etched wafer and the quantity of silicon removed for a given etching environment.

According to the process of the present invention, therefore, the concentration of hydrofluoric acid and diluent in the aqueous etching solution is determined by etching a silicon sample in essentially the same etching environment in which subsequent silicon wafers will be etched. More specifically, the silicon sample is etched in the same etching apparatus using substantially identical operating conditions, such as the temperature and hydrodynamics of the aqueous etching solution relative to the wafer. Preferably the silicon sample has been prepared using similar shaping and cleaning processes such that the crystal morphology of the surface of the silicon sample is similar to the silicon wafer. More preferably, the silicon sample is sliced from a single crystal silicon ingot and further shaped and cleaned using process steps identical to the silicon wafer prior to etching. Accordingly, the silicon sample is preferably a silicon wafer similar to the wafers to be etched.

The silicon sample is contacted with a first calibrated aqueous etching solution comprising a known concentration of hydrofluoric acid and, optionally, a known concentration of diluent and at least a stoichiometric quantity of oxidizing agent for a period of time to remove a quantity of silicon from the surface of the sample in the etching environment. The particular etching environment may be selected from any environment used to etch the surface of single crystal silicon wafers. For example, the surface of the wafer may be contacted with the aqueous etching solution by spin etching, wherein one surface of the wafer is placed on a rotatable chuck, and the aqueous etching solution is sprayed on the surface apposing the surface attached to the chuck, while the wafer is rotated at high speed. While not critically narrow, the rotation speed of the chucked wafer ranges from about 10 to about 1000 rotations per minute.

Alternatively, a vertical etching apparatus may be used, wherein one or more wafers are rotated while being submersed in the aqueous etching solution. Vertical etching processes frequently include bubbling a non-reactive gas (e.g., nitrogen, oxygen, and noble gases such as helium, and argon, and compound gases such as carbon dioxide) through the etching solution during the etching process. These extrinsic bubbles enhance the efficiency of the etching process by improving the mixing in the vertical etching apparatus. Surprisingly, the extrinsic bubbles provide the additional benefit of aiding in the detachment of the intrinsic bubbles from the surface of the wafer, thus reducing the effective mass transfer resistance, R_{m,eff,i}, and the corresponding bubble masking effect. However, the extrinsic bubbles can also adhere to the surface of the wafer upon moving the wafer from the vertical etching apparatus to a quick dump rinse tank used to rinse residual aqueous etching solution from the wafer surface. Thus, the bubbling of the non-reactive gas is preferably terminated for a dwell time period prior to removing the immersed wafer from the aqueous etching solution to allow, at least substantially, all non-reactive gas bubbles in contact with the wafer surface to detach from the surface of the wafer.

Preferably, the concentration of the oxidizing agent and the hydrofluoric acid is maintained at a constant value by adding oxidizing agent and hydrofluoric acid at concentrations of at least about the concentration of the selected etching solution during the etching process at a rate and concentration sufficient to maintain the concentration of the aqueous etching solution at approximately the concentration of the initial selected aqueous etching solution until the etching is complete. More preferably, the additional oxidizing agent and hydrofluoric acid are added in concentrations greater than the initial concentration as required by mass balance. Accordingly, hydrofluoric acid having a concentration of at least about 10% by weight, more preferably at least about 25% by weight, and even having a concentration of 50% by weight or greater may be added during the etching process at a rate sufficient to maintain the concentration of hydrofluoric acid in the mixed acid tank throughout the etching process. Similarly, an oxidizing agent, such as nitric acid for example having a concentration of at least 50% by weight, and more preferably at least about 70% by weight or greater is continuously added during the etching process to maintain the concentration of oxidizing agent above the stoichiometric concentration required to oxidize the silicon to be removed. Under typical etching processes, multiple wafers are etched causing a significant reduction in the concentration of reactants, thus requiring additions to be made to maintain a constant concentration. It should be noted that the relationship between reactant concentrations and surface quality to removal quantity can be determined using a single wafer resulting in little reduction in concentration, thus additional reactants may not need to be added during this step. That is, if only a single wafer or a small number of wafers is used when determining the reactant concentrations required to provide the desired polishing efficiency, it may not be necessary to continuously replenish the reactants during the etching process in order to maintain the concentration of the solution.

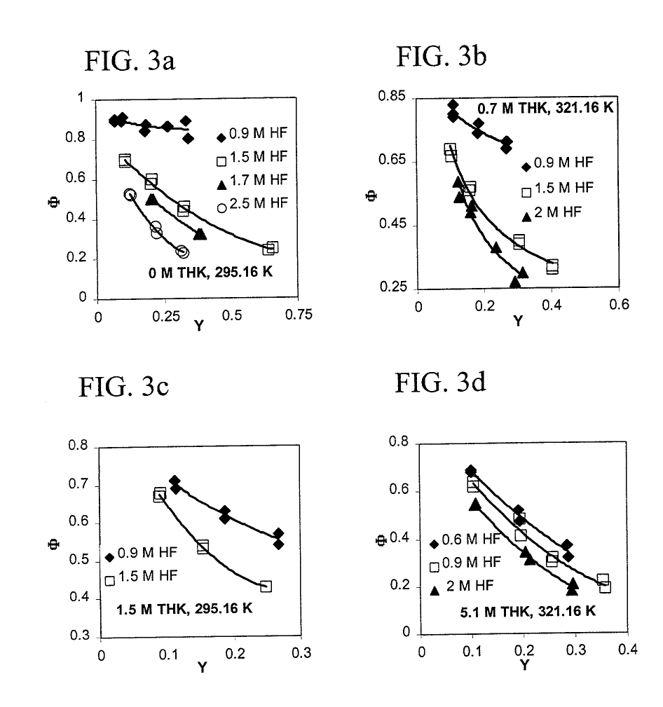

After a quantity of silicon has been removed from the surface of the silicon sample, the silicon sample is measured to determine the quantity of silicon removed from the surface of the sample. In addition, the surface of the etched sample is measured to determine the gloss or roughness of the surface. Next, a second silicon sample is contacted with the same aqueous etching solution for a different contact time, such that a different quantity of material is removed from the sample. The second silicon sample is then measured to determine the quantity of silicon removed from the surface of the second sample and the surface of the etched second sample is measured to determine the gloss or roughness of the surface. Thus, the relationship between the surface quality and the quantity of silicon removed from the surface of the samples in the etching environment for the first calibrated aqueous etching solution can be determined. The relationship can then be graphically displayed by plotting the surface quality verses the quantity of silicon removed from the surface, such that a linear or non-linear approximation of the relationship can be determined by drawing a line through the two data points or a curve through many data points. Preferably, additional silicon samples are etched for various contact times using the first calibrated aqueous etching solution to produce additional data that can be used to form more accurate representations of the relationship. Similar relationships are determined using additional calibrated aqueous etching solutions having various known concentrations of hydrofluoric acid and diluent such that for each calibrated aqueous etching solution the relationship between surface quality and removal quantity can be empirically determined for the various compositions of aqueous etching solutions for a given etching environment as shown in FIGS. 3a through 3d.

The range of concentrations within which the various calibrated aqueous solutions are selected will vary according to the etching environment of the etching process. For example, for a typical industrial etching apparatus such as a vertical etching apparatus, the hydrofluoric acid concentrations in the various calibrated aqueous etching solutions are preferably selected to have concentrations ranging from about 0.5% by weight to about 15% by weight; concentrations greater than about 15% by weight may be used depending on the etching environment. In addition, the diluent concentrations in the various calibrated aqueous etching solutions are preferably selected to have concentrations ranging from 0% by weight to about 8% by weight for phosphoric acid, and from 0% by weight to about 35% by weight for acetic acid. As with the hydrofluoric acid, these ranges may vary depending on the etching environment.

In addition to the graphical determination of the relationship between the surface quality of the etched surface and the quantity of silicon removed based on the data obtained for the silicon samples, a relationship may also be determined by mathematically modeling the ratio of surface quality to removal quantity as a function of both the hydrofluoric acid concentration and the diluent concentration. Any means may be employed for mathematically modeling the surface profile data including, but not limited to, computer software programs designed to model three dimensional surfaces. Persons skilled in the art are aware of such computer software programs suitable for three dimensional modeling. For example, Matlab software is available from The MathWorks Inc., Natick, Mass. and is suitable for three dimensional mathematical modeling. However, while the relationship between surface quality and removal quantity can be modeled as a function of effective mass transfer resistance, R_{m,eff,i}, to kinetic resistance, R_{r,i}, the critical ratio of effective mass transfer resistance, R_{m,eff,i}, to kinetic resistance, R_{r,i}, for bubble masking varies with the etching environment and the components selected for the etching solution; hence, the relationship between surface quality and removal quantity is modeled as a function of effective mass transfer resistance, R_{m,eff,i}, to kinetic resistance, R_{r,i}, for each etching solution type for each etching environment.

According to the process of the present invention, once the desired surface quality to removal quantity is selected, an aqueous etching solution may be determined based on the empirically determined relationships. Thus, the process of the present invention will produce an etched wafer having the desired surface quality after removing the desired removal quantity.

In another embodiment of the present invention, it has been discovered that a process for etching a silicon wafer having a hard laser marked bar code on at least one surface to remove silicon from the surface to provide an improved surface quality on the etched surface wherein the hard laser marked bar code on the etched wafer has not been substantially deteriorated. Deterioration of the geometry of the dots formed by the hard laser marked bar coding processes can cause “laser dot blowout”, wherein the diameter of the laser dots swell such that the bar code is no longer readable by standard bar code reading devices. Accordingly, a hard laser marked bar code does not become “substantially deteriorated” until the bar code is no longer readable. According to the process of the present embodiment, therefore, the concentration of the aqueous etching solution is selected to reduce bubble masking effects such that a silicon wafer having a hard laser marked bar code may be etched in a vertical etching environment without substantially deteriorating the hard laser marked bar code.

According to this embodiment, a hard laser marked bar code is first produced on the surface of a wafer, the wafer having previously been sliced from a single crystal silicon ingot and further optionally processed using conventional edge profiling, grinding, lapping and cleaning processes as described above. Typically, after hard laser marking the wafer goes through additional mechanical shaping processes, such as lapping, although in some cases it may not be necessary. The hard laser marked wafer is then placed in a mixed acid etch tank, wherein the hard laser marked wafer and, more preferably, a population of hard laser marked wafers are rotated while being contacted with an aqueous etching solution. Although the precise number of wafers etched in a single bath is not critically narrow, typically 25 wafers are etched at a time, wherein said wafers are held in a support and rotated during the etching process.

The aqueous etching solution is comprised of hydrofluoric acid and an oxidizing agent. The aqueous etching solution has a concentration of the hydrofluoric acid of at least about 0.8% by weight, more preferably at least about 0.8% by weight to about 9.5% by weight, and a concentration of oxidizing agent in excess of the stoichiometric concentration required to oxidize the surface, and is substantially free of any diluents such as phosphoric acid, acetic acid and sulfuric acid. Alternatively, the etching solution may further comprise a concentration of diluent wherein the concentration is less than about 8% by weight if the diluent is phosphoric acid, and less than about 35% by weight if the diluent is acetic acid. Preferably, the diluent concentration in the aqueous etching solution is such that the viscosity of the aqueous etching solution is less than about 50 centipoise.

Additional oxidizing agent, hydrofluoric acid and if used, diluent are added to the aqueous etching solution during the etching process at rates and concentrations specific to each reactant which are sufficient to maintain the composition of the aqueous etching solution during the etching process. In this manner, the process of the present invention may be used in batch, semi-batch or continuous etching processes. Preferably, the concentrations of the additional oxidizing agent and hydrofluoric acid added are greater than the initial concentration in the mixed acid tank. Accordingly, hydrofluoric acid having a concentration of at least about 10% by weight, more preferably at least about 25% by weight, and even having a concentration of 50% by weight or greater may be added during the etching process at a rate sufficient to maintain the concentration of hydrofluoric acid throughout the etching process. Similarly, an oxidizing agent, such as nitric acid for example, having a concentration of at least 50% by weight, and more preferably at least about 70% by weight or greater is added to maintain the concentration of oxidizing agent above the stoichiometric concentration required to oxidize the silicon to be removed. If the aqueous etching solution further comprises a diluent, additional diluent should be added to maintain the concentration during the etching process.

Preferably, the aqueous etching solution is in the form of a froth formed by bubbling one or more non-reacting gases through the aqueous etching solution as described in U.S. Pat. No. 6,046,117. These non-reacting gases include elemental gases such as nitrogen, oxygen, and noble gases such as helium, and argon, and compound gases such as carbon dioxide. Furthermore, the bubbling of the non-reactive gas is preferably terminated for a dwell time period prior to removing the immersed wafer from the aqueous etching solution to allow, at least substantially, all inert gas bubbles in contact with the wafer surface to detach from the surface of the wafer.

The wafer is rotated at a speed less than about 20 rpm, preferably at a speed less than about 15 rpm, and most preferably at a speed of about 5 rpm while being maintained in contact with the aqueous etching solution. Depending on the etching rates, the wafer rotation speed may vary. Thus, rotation speeds greater than 20 rpm or less than 5 rpm can be used without departing from the scope of the present invention. The surface of the wafer remains in contact with the aqueous etching solution for about 30 seconds to about 200 seconds or until the desired amount of stock is remove from the wafer. The wafer is then removed from the aqueous etching solution and immediately rinsed with deionized water. Alternatively, other rinsing solutions known in the art may be used in place of the deionized water. Preferably, the wafer is maintained in contact with the aqueous solution for a time period required to remove at least about 5.0 μm, at least about 15 μm, and even at least about 30 μm or greater. The depth and diameter of laser dots before etching varies based on customer specifications. Typically laser dots before etching are about 50 μm to 150 μm wide and about 50 μm to 200 μm deep. An aqueous etching mixture of hydrofluoric acid and nitric acid may remove practically any amount of stock without eliminating the laser mark readability. That is, the hard laser marked bar code remaining on the etched surface of the wafer after removing the desired quantity of silicon according to the etching process of the present invention is not substantially deteriorated.

### EXAMPLES

Silicon wafers having a surface containing a hard laser marked bard code were etched using varying concentrations of aqueous etching solutions in a vertical etching apparatus. Initial concentrations were selected based on experimentally determined gloss to removal data to provide an etching environment with reduced bubble masking effects. The silicon wafers were etched by fast, moderate, slow, fast-dwell and moderate-dwell etching processes wherein the fast process contained a high concentration of hydrofluoric acid and no diluent, the moderate process contained a medium concentration of hydrofluoric acid and no diluent, and the slow process contained a low concentration of hydrofluoric acid and a low concentration of phosphoric acid, each being designed to manipulate the effective mass transfer resistance, R_{m,eff,i}, to kinetic resistance, R_{r,i}, such that the ratio is less than that critical ratio at which significant bubble masking effects occur.

Because of equipment limitations, the fast-dwell and moderate-dwell processes were run in a cyclic mode. Each cycle consisted of two semi-cycles. The first semi-cycle involved etching wafers in a mixed acid etch tank while hydrofluoric acid and nitric acid were added at a known rate. The second semi-cycle involved further addition of nitric acid but no hydrofluoric acid. The remaining processes, i.e., fast, moderate and slow processes, were run in under normal conditions which involved a one time addition of hydrofluoric acid and nitric acid at given rates for each etching period.

Process parameters for each process are compared with process parameters for conventional three component etching processes in Table 1.

TABLE 1
A Parametric Comparison Between the Modified and
Conventional Processes.

| Process | Spiking Ratio | | | |
|---|---|---|---|---|
| Description | (HF:HNO₃:H₂PO₄) | T (° C.) | t_{etch}:t_{dwell} | Comments |
| Fast etch | 638:1960.0:0 | 22 | 43:0 | Good bar code, High rates, |
| | | | | stains |
| Medium etch | 349.8:(1004.5 + 1003.8) | 22 | 130:0 | Good bar code, moderately |
| | | | | high removal |
| Slow etch | 190:992:137 | 22 | 200:0 | Good bar code, High removal |
| Fast etch with | 660:980 (Full cassette | 22 | 55:12 | Good bar code, Feasible with |
| dwell time | run) + 0:980 (empty | | | caution |
| | cassette run) | | | |
| Medium etch | 400:992 (Full cassette | 22 | 70:12 | Good bar code |
| with dwell | run) + 0:992 (empty | | | |
| time | cassette run) | | | |
| Conventional | 200:980:660 | 35 | 150:15 | Bad bar code |
| etch | | | | |

The throughput of the fast and moderate processes are greater than the throughput of the conventional process. The throughput of the slow process was less than conventional etch rates. All of the processes of the present invention yield 100% readable bar codes.

Table 2 shows a comparison of the average and standard deviation of the total thickness variation (TTV) before and after etching, the removal quantity, the change in total thickness variation (ΔTTV), and the gloss.

TABLE 2
A Statistical Comparison Between Modified and Standard Processes.

| | | | | Fast | Med. | Standard | Standard |
|---|---|---|---|---|---|---|---|
| | Fast | Medium | Slow | w/dwell | w/dwell | (Tech) | (APD) |
| | (avg-σ) | (avg-σ) | (avg-σ) | (avg-σ) | (avg-σ) | (avg-σ) | (avg-σ) |
| Pre etch | 0.62-0.13 | 0.7-0.153 | 0.79-0.2 | 0.68-0.19 | 0.72-0.17 | | 0.81-0.21 |
| TTV | | | | | | | |
| P−P+ | | | | | | | |
| (μm) | | | | | | | |
| TTV | 1.12-0.2 | 1.168-0.2 | 1.14-0.27 | 1.74-0.22 | 1.64-0.22 | | 1.12-0.26 |
| P−P+ | | | | | | | |
| (μm) | | | | | | | |
| TTV | 1.1-0.21 | 1.19-0.356 | 1.19-0.28 | 1.87-0.21 | 1.66-0.19 | | |
| P− | | | | | | | |
| (μm) | | | | | | | |
| TTV | 1.15-0.16 | 1.16-0.164 | 1.07-0.229 | 1.61-0.17 | 1.63-0.25 | | |
| P+ | | | | | | | |
| (μm) | | | | | | | |
| Removal | 22.95-0.93 | 27.77-0.76 | 33.1-1.57 | 24.96-0.6 | 33.73-1.13 | | 19.96-1.01 |
| P−P+ | | | | | | | |
| (μm) | | | | | | | |
| Removal | 23.3-0.97 | 27.99-0.5 | 32.52-1.65 | 25.12-0.51 | 35.15-1.41 | | |
| P− | | | | | | | |
| (μm) | | | | | | | |
| Removal | 22.31-0.31 | 27.46-0.95 | 33.99-0.87 | 24.65-0.66 | 33.07-0.44 | | |
| P+ | | | | | | | |
| (μm) | | | | | | | |
| ΔTTV | 0.5-0.21 | 0.46-0.17 | 0.36-0.24 | 1.05-0.24 | 0.92-0.24 | | |
| P−P+ | | | | | | | |
| (μm) | | | | | | | |
| ΔTTV | 0.55-0.22 | 0.51-0.16 | 0.38-0.25 | 1.24-1.65 | 0.98-0.36 | | |
| P− | | | | | | | |
| (μm) | | | | | | | |
| ΔTTV | 0.41-0.14 | 0.39-0.16 | 0.33-0.22 | 0.99-0.18 | 0.88-0.2 | | |
| P+ | | | | | | | |
| (μm) | | | | | | | |
| Gloss | 201-8.13 | 144-19.87 | 224-28.88 | 210-15.18 | 245-20.18 | 186-31.31 | |
| P−P+ | | | | | | | |
| (gu) | | | | | | | |
| Gloss | 198-6.91 | 130-11.18 | 206-20.24 | 201-9.55 | 220-6.87 | 196-28.74 | 166-28.22 |
| P− | | | | | | | |
| (gu) | | | | | | | |
| Gloss | 206-7.67 | 164-11.22 | 253-10.80 | 227-8.29 | 259-7.89 | 157-15.87 | |
| P+ | | | | | | | |
| (gu) | | | | | | | |

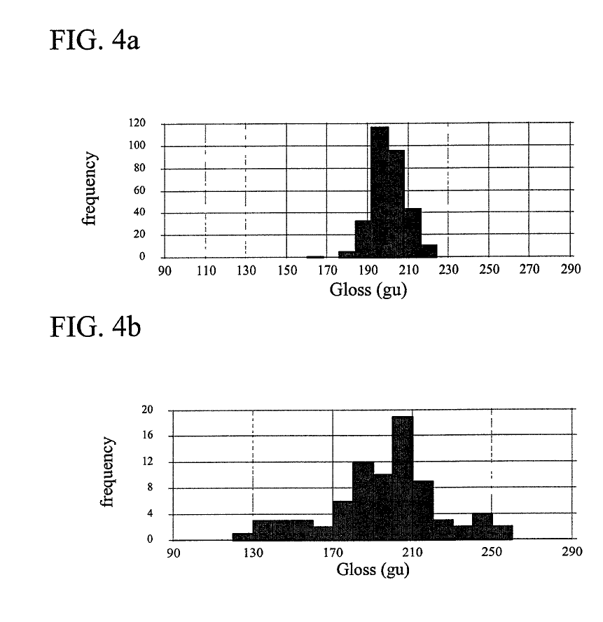

It should be noted that the parameters shown in Table 2 for all processes are within the specified range. That is, all processes meet the specifications of the conventional process. It should be further noted that the product variability for each of the processes of the present invention is lower than the product variability of the conventional process. For example, the variability in the gloss value of wafers etched by the fast etch process is much lower than the gloss value of wafers etched by conventional process as shown by the gloss-frequency histograms for the fast and conventional processes depicted in FIGS. 4a and 4b.

Essentially all measured parameters, such as TTV, gloss and roughness, are influenced by the uniformity of flow dynamics. Flow uniformity in mixed acid etch tank improves with decreasing viscosity. Since acid mixture used in the process of the present invention is less viscous than conventional processes, product variability for the processes of the present invention is substantially reduced.

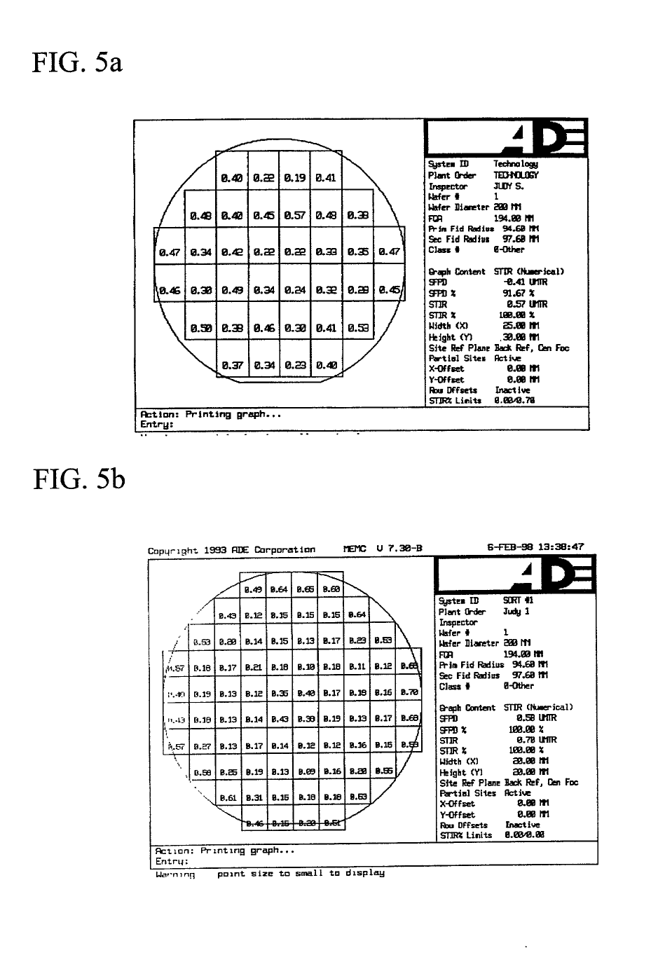

FIGS. 5a and 5b shows the comparison in the local flatness of wafers etched by the conventional process and wafers etched by the present invention. It should be noted that while the process of the present invention produced marginally reduced flatness near the perimeter, the flatness is nevertheless acceptable for device manufacturing. In addition, it is believed that the reduced flatness near the perimeter is caused by high rotation speeds and can be improved for moderate and slow processes by decreasing wafer rotation speed.

During the performance of the experiment, the test wafers were transported from one location to another, wherein they were stored for extended periods of time and were mechanically handled under conditions not typical of etching processes resulting in significant stain loss caused by handling of wafers. Therefore, wafer transport and process related stain losses, such as brown stain and burns, were grouped separately from handling related stain losses for stain loss analysis. Stain losses for different processes are compared in Table 3.

TABLE 3
Stain Loss Data for Standard and Modified Processes

| | | | | | | | | | | Fast Etch w/ | | | Medium Etch | | |
|---|---|---|---|---|---|---|---|---|---|---|---|---|---|---|---|
| | Fast Etch | | | Medium Etch | | | Slow Etch | | | dwell | | | w/dwell | | |
| | P− | P+ | All | P− | P+ | All | P− | P+ | All | P− | P+ | All | P− | P+ | All |
| No of | 220 | 110 | 330 | 220 | 132 | 352 | 220 | 110 | 330 | 110 | 88 | 198 | 44 | 44 | 88 |
| Wafers Etched | | | | | | | | | | | | | | | |
| No. of Brown | 0 | 46 | 46 | 0 | 0 | 0 | 0 | 0 | 0 | 1 | 6 | 7 | 0 | 1 | 1 |
| Stains | | | | | | | | | | | | | | | |
| No. of Burns | 5 | 2 | 7 | 6 | 7 | 13 | 2 | 2 | 4 | 0 | 0 | 0 | 0 | 0 | 0 |
| Brown Stains | 0 | 42 | 14 | 0 | 0 | 0 | 0 | 0 | 0 | 1 | 7 | 3.5 | 0 | 2 | 1.1 |
| (%) | | | | | | | | | | | | | | | |
| Burns (%) | 2.3 | 1.8 | 2.1 | 2.7 | 5 | 3.4 | 1 | 1.8 | 1.2 | 0 | 0 | 0 | 0 | 0 | 0 |

It is evident that stain losses decrease with decreasing etch rates. Although marginally higher than the standard stain loss, stain losses for moderate and slow processes appear to be acceptable.

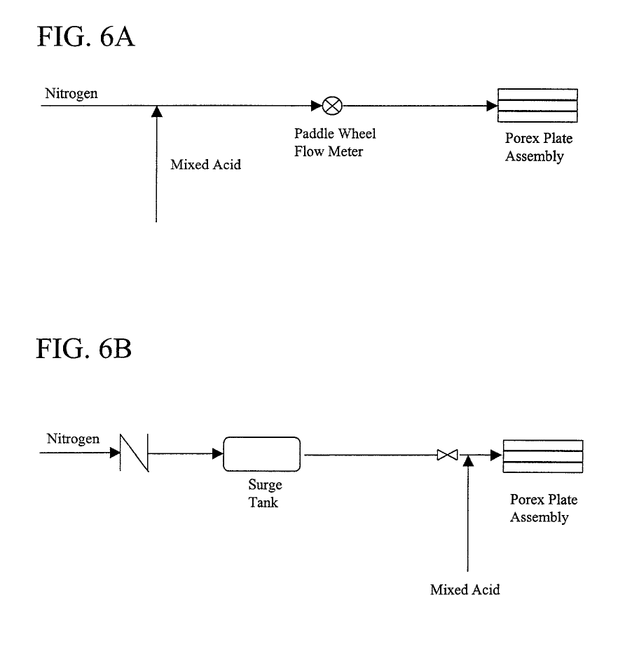

All the processes discussed above were run in the etching configuration shown in FIG. 6a. The moderate process was also run in the configuration shown in FIG. 6b. The modified etching configuration uses a surge tank in the nigrogen line to help dampen fluctuations in the nitrogen flow. In addition, higher-capacity spiking pumps were used in the modified-moderate process.

A number of wafers were etched using a moderate etching solution along with the modified configuration and higher spike rates. The total thickness variation (TTV) before and after etching are shown in Table 4.

TABLE 4
Results of modified-moderate etch
Initial makeup: HF = 9.75 liters (6.5% by volume): HNO3 = 140 liters
Spiking rates: HF = 480 ml/min; HNO3 = 3532 ml/min.

| | Slot | Pre-etch | Post-etch | Post-polish | Pre-etch | Post-etch | Post-polish |
|---|---|---|---|---|---|---|---|
| Lot Number | # | TTV UMTR | TTV UMTR | TTV UMTR | STIR UMTR | STIR UMTR | STIR UMTR |
| 819904B001 | 2 | 2.01 | 1.87 | 1.59 | 0.23 | 0.45 | 0.18 |
| | 7 | 2.49 | 3 | 1.18 | 0.32 | 0.46 | 0.15 |
| | 12 | 2.28 | 2.27 | 2.45 | 0.19 | 0.44 | 0.18 |
| 819904B002 | 2 | 1.02 | 0.94 | 0.27 | 0.17 | 0.42 | 0.24 |
| | 7 | 1.02 | 0.85 | 0.42 | 0.16 | 0.44 | 0.26 |
| | 12 | 1.14 | 1.34 | 0.44 | 0.22 | 0.42 | 0.25 |
| 819904B003 | 2 | 1.02 | 1.07 | 0.74 | 0.18 | 0.44 | 0.21 |
| | 7 | 1.13 | 1.15 | 0.48 | 0.21 | 0.5 | 0.22 |
| 819904B005 | 2 | 1.12 | 0.94 | 0.53 | 0.2 | 0.37 | 0.19 |
| | 7 | 1.35 | 1.19 | 0.33 | 0.22 | 0.42 | 0.24 |
| | 12 | 1.24 | 1.43 | 0.47 | 0.21 | 0.42 | 0.22 |
| | 17 | 1.46 | 1.42 | 0.24 | 0.24 | 0.42 | 0.22 |
| 819904B007 | 2 | 1.09 | 1.05 | 0.36 | 0.19 | 0.49 | 0.21 |
| | 7 | 1.15 | 1.06 | 0.31 | 0.22 | 0.49 | 0.25 |
| | 12 | 1.21 | 1.09 | 0.46 | 0.24 | 0.49 | 0.27 |
| | 17 | 1.41 | 1.29 | 0.64 | 0.25 | 0.42 | 0.27 |
| 819904B008 | 2 | 1.39 | 1.33 | 0.64 | 0.33 | 0.57 | 0.2 |
| | 7 | 1.52 | 1.14 | 0.93 | 0.33 | 0.45 | 2.86 |
| | 12 | 1.37 | 1.51 | 1.01 | 0.3 | 0.5 | 0.2 |
| | 17 | 1.9 | 1.59 | 0.85 | 0.33 | 0.54 | 0.18 |
| 819904B009 | 2 | 1.16 | 1.5 | 0.39 | 0.2 | 0.56 | 0.22 |
| | 7 | 1.3 | 1.51 | 0.72 | 0.23 | 0.41 | 0.23 |
| | 12 | 1.41 | 1.68 | 0.79 | 0.27 | 0.47 | 0.22 |
| 819904B010 | 2 | 1.33 | 1.12 | 0.48 | 0.28 | 0.54 | 0.35 |
| | 7 | 1.94 | 1.58 | 0.65 | 0.35 | 0.55 | 0.34 |
| | 12 | 1.77 | 1.85 | 1.06 | 0.35 | 0.5 | 0.35 |
| 819904B012 | 2 | 0.98 | 0.9 | 0.36 | 0.16 | 0.46 | 0.22 |
| | 7 | 1.1 | 1.17 | 0.33 | 0.21 | 0.42 | 0.24 |
| | 12 | 1.13 | 1.08 | 0.52 | 0.21 | 0.55 | 0.22 |
| | 17 | 1.14 | 0.99 | 0.3 | 0.19 | 0.41 | 0.24 |
| 819904B013 | 2 | 1.07 | 1.03 | 0.8 | 0.19 | 0.7 | 0.37 |
| | 7 | 1.33 | 1.3 | 0.88 | 0.24 | 0.51 | 0.38 |
| | 12 | 1.2 | 1.09 | 0.92 | 0.25 | 0.57 | 0.38 |

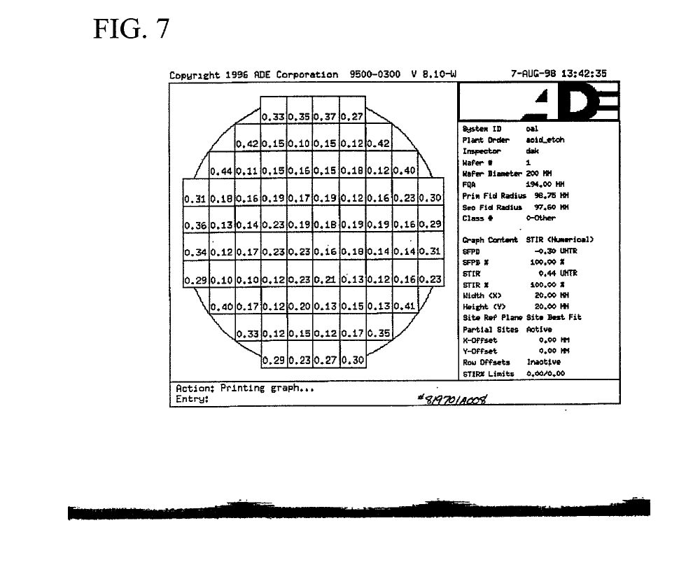

In each cycle, 22 wafers in a wafer cassette were etched. Wafers from slots 2, 7 and 12 from each cassette were characterized and the results obtained are listed in Table 4. The flatness performance of this process is shown in FIG. 7. It should be noted that the performance of the modified-moderate process meets standards of the current industrial etching processes. Furthermore, the process yields 100% laser-marked bar code readability.

In view of the above, it will be seen that the several objects of the invention are achieved. As various changes could be made in the above-described process without departing from the scope of the invention, it is intended that all matters contained in the above description be interpreted as illustrative and not in a limiting sense. In addition, when introducing elements of the present invention or the preferred embodiment(s) thereof, the articles “la,” “an,” “the” and “said” are intended to mean that there are one or more of the elements. The terms “comprising,” “including” and “having” are intended to be inclusive and mean that there may be additional elements other than the listed elements.

What is claimed is:

1. A process for etching a surface of a silicon wafer in an etching environment, the process comprising:
selecting a desired surface quality for the surface of the etched wafer and a desired quantity of silicon to be removed from the surface of the wafer during the etching process;
determining the concentration of hydrofluoric acid in an aqueous etching solution comprising hydrofluoric acid and an oxidizing agent that will produce an etched wafer such that the surface of the etched wafer has the desired surface quality once the desired quantity of silicon has been removed from the surface of the wafer in the etching environment; and
contacting the surface of the silicon wafer with the aqueous etching solution in the etching environment for a time period sufficient to remove the desired quantity of silicon from the surface.

2. The process of claim 1 wherein the concentration of the oxidizing agent in the aqueous etching solution is at least the stoichiometric concentration required to oxidize the desired quantity of silicon to be removed from the wafer.

3. The process of claim 1 wherein the oxidizing agent is selected from the group consisting of potassium permanganate, potassium dichromate, ozone, peroxide, nitric acid and mixtures thereof.

4. The process of claim 1 wherein the aqueous etching solution is substantially free of a diluent.

5. The process of claim 4 wherein the concentration of hydrofluoric acid in the aqueous etching solution is determined by:
(a) etching a silicon sample in the etching environment by contacting the sample with a calibrated aqueous etching solution comprising a known concentration of hydrofluoric acid and an oxidizing agent for a period of time to remove a quantity of silicon from the surface of the sample;
(b) determining the quantity of silicon removed from the surface of the sample in step (a) and the surface quality of the etched sample;
(c) repeating steps (a) and (b) for different contact times to determine the relationship between the surface quality and the quantity of silicon removed from the surface of the sample in the etching environment for the concentration of hydrofluoric acid in the calibrated aqueous etching solution of step (a);
(d) repeating steps (a) through (c) using calibrated aqueous etching solutions having various known concentrations of hydrofluoric acid; and
(e) determining the concentration of hydrofluoric acid in the aqueous etching solution that will produce an etched wafer such that the surface of the etched wafer has the desired surface quality once the desired quantity of silicon has been removed from the surface of the etched wafer in the etching environment based on the relationships between the surface quality and the quantity of silicon removed from the surface of the sample in the etching environment for the calibrated aqueous etching solutions of steps (a) through (d).

6. The process of claim 1 wherein the aqueous etching solution comprises a diluent, the process further comprising determining the concentration of hydrofluoric acid and diluent in the aqueous etching solution that will produce an etched wafer such that the surface of the etched wafer has the desired surface quality once the desired quantity of silicon has been removed from the surface of the wafer in the etching environment.

7. The process of claim 6 wherein the diluent is selected from the group consisting of acetic acid, phosphoric acid, sulfuric acid and mixtures thereof.

8. The process of claims 6 wherein the concentration of hydrofluoric acid and diluent in the aqueous etching solution is determined by:
(a) etching a silicon sample in the etching environment by contacting the sample with a calibrated aqueous etching solution comprising a known concentration of hydrofluoric acid and a known concentration of diluent and an oxidizing agent for a period of time to remove a quantity of silicon from the surface of the sample;
(b) determining the quantity of silicon removed from the surface of the sample in step (a) and the surface quality of the etched sample;
(c) repeating steps (a) and (b) for different contact times to determine the relationship between the surface quality and the quantity of silicon removed from the surface of the sample in the etching environment for the concentration of hydrofluoric acid and diluent in the calibrated aqueous etching solution of step (a);
(d) repeating steps (a) through (c) using calibrated aqueous etching solutions having various known concentrations of hydrofluoric acid and various known concentrations of diluent; and
(e) determining the concentration of hydrofluoric acid and diluent in the aqueous etching solution that will produce an etched wafer such that the surface of the etched wafer has the desired surface quality once the desired quantity of silicon has been removed from the surface of the etched wafer in the etching environment based on the relationships between the surface quality and the quantity of silicon removed from the surface of the sample for the calibrated aqueous etching solutions of steps (a) through (d).

9. The process of claim 1 wherein the surface quality is selected from a group consisting of roughness and gloss.

10. The process of claim 1 wherein the wafer is contacted with the aqueous etching solution by immersing the wafer in the aqueous etching solution;

11. The process of claim 10 further comprising bubbling an inert gas through the aqueous etching solution.

12. The process of claim 11 wherein the inert gas is selected from the group consisting of nitrogen, argon and air.

13. The process of claims 11 wherein bubbling of an inert gas is terminated for a dwell time period prior to removing the immersed wafer from the aqueous etching solution, the dwell time period being at least long enough to allow at least substantially all inert gas bubbles in contact with the wafer surface to detach from the surface of the wafer.

14. The process of claims 10 further comprising adding additional oxidizing agent to the aqueous etching solution during the etching process at a rate sufficient to maintain at least the stoichiometric concentration required to oxidize the desired quantity of stock to be removed from the wafer to maintain the oxidizing agent concentration in the etching solution throughout the etching process.

15. The process of claim 10 wherein additional diluent is added during the etching process at a rate sufficient to maintain the diluent concentration in the aqueous etching solution throughout the etching process.

16. The process of claim 10 wherein additional hydrofluoric acid is added during the etching process at a rate sufficient to maintain the hydrofluoric acid concentration in the etching solution throughout the etching process.

17. The process of claim 1 wherein the desired quantity of silicon to be removed from the surface of the wafer is a layer of silicon extending from the surface of the wafer towards the interior of the wafer for a distance of at least about 5 microns.

18. The process of claim 1 wherein the desired quantity of silicon to be removed from the surface of the wafer is a layer of silicon extending from the surface of the wafer towards the interior of the wafer for a distance of at least about 15 microns.

19. The process of claim 1 wherein the desired quantity of silicon to be removed from the surface of the wafer is a layer of silicon extending from the surface of the wafer towards the interior of the wafer for a distance of at least about 30 microns.

20. The process of claim 1 wherein the etching solution has a viscosity of less than about 50 Centipoises.

21. A process for etching a silicon wafer having a surface, and a hard laser marked bar code on the surface, the process comprising:
contacting the surface of the wafer with an aqueous etching solution, comprising hydrofluoric acid and an oxidizing agent, wherein the concentration of the aqueous etching solution is selected to reduce a bubble masking effect such that the hard laser marked bar code on the etched surface is not significantly distorted such that the readability of the hard laser marked bar code is not diminished.

22. The process of claim 21 wherein the etching solution comprises a concentration of hydrofluoric acid of at least about 0.8% by weight.

23. The process of claims 21 wherein the etching solution is substantially free of phosphoric acid and acetic acid.

24. The process of claim 23 wherein the etching solution comprises a concentration of hydrofluoric acid of about 0.8% by weight to about 9.5% by weight.

25. The process of claim 21 wherein the etching solution further comprises a concentration of phosphoric acid of no greater than about 8% by weight.

26. The process of claim 21 wherein the etching solution further comprises a concentration of acetic acid of no greater than about 35% by weight.

27. The process of claim 21 wherein the etching solution has a viscosity of less than about 50 Centipoises.
